(19) United States
(12) Patent Application Publication
(10) Pub. No.: US 2016/0071892 A1
(43) Pub. Date: Mar. 10, 2016

(54) DOPANT CONFIGURATION IN IMAGE SENSOR PIXELS

(71) Applicant: OMNIVISION TECHNOLOGIES, INC., Santa Clara, CA (US)

(72) Inventors: Gang Chen, San Jose, CA (US); Philippe Matagne, Nandrin (BE); Chih-Wei Hsiung, San Jose, CA (US); Yuanwei Zheng, San Jose, CA (US); Duli Mao, Sunnyvale, CA (US); Dyson H. Tai, San Jose, CA (US)

(21) Appl. No.: 14/478,931

(22) Filed: Sep. 5, 2014

(51) Int. Cl. H01L 27/146; H04N 5/374; H04N 5/378

(52) U.S. Cl. CPC H01L 27/1461; H04N 5/378; H04N 5/374; H01L 27/14605; H01L 27/14616; H01L 27/14689

(57) ABSTRACT

An image sensor pixel including a photodiode includes a first dopant region disposed within a semiconductor layer and a second dopant region disposed above the first dopant region and within the semiconductor layer. The second dopant region contacts the first dopant region and the second dopant region is of an opposite majority charge carrier type as the first dopant region. A third dopant region is disposed above the first dopant region and within the semiconductor layer. The third dopant region is of a same majority charge carrier type as the second dopant region but has a greater concentration of free charge carriers than the second dopant region. A transfer gate is positioned to transfer photogenerated charge from the photodiode. The second dopant region extends closer to an edge of the transfer gate than the third dopant region.

### TECHNICAL FIELD

This disclosure relates generally to image sensors, and in particular but not exclusively, relates to dopant configuration in image sensor pixels.

### BACKGROUND INFORMATION

An image sensor is an electronic device that converts light (in the form of an optical image) into electronic signals. Modern image sensors are generally semiconductor charge-coupled devices (“CCD”) or active pixel sensors fabricated in complementary metal-oxide-semiconductor (“CMOS”) technologies.

CMOS image sensors have become ubiquitous in many modern electronic devices. Cell phones, laptops, and cameras can all utilize CMOS image sensors as a primary method of image/light detection and device manufacturers and consumers desire high performance. One way to enhance the performance of image sensors is to increase pixel density.

With CMOS image sensor pixel pitch scaling down, new pixel design is needed to improve optical/electrical performance. Increasing the number of cell shared pixels is an effective way to maximize photodiode area at a given pixel pitch. However, increasing the number of multiple cell shared pixels generally requires more implantation steps and multiple deposition angles to achieve the desired device architecture. Hence, a multiple cell shared device that requires fewer process steps and/or exhibits greater electronic performance would be highly desirable.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1A is a top-down view of a shared pixel that includes four image sensor pixels, in accordance with an embodiment of the disclosure.

FIG. 1B is a cross sectional view of the shared pixel in FIG. 1A as cut along the line A-A′, in accordance with an embodiment of the disclosure.

FIG. 2 is a block diagram illustrating one example of an image sensor, in accordance with an embodiment of the disclosure.

FIGS. 3A-3E show a process for forming an image sensor pixel, in accordance with an embodiment of the disclosure.

FIG. 3F is a magnified view of the structure within the dashed line of FIG. 3E, in accordance with an embodiment of the disclosure.

FIG. 4 is a flowchart of a process for forming an image sensor pixel, in accordance with an embodiment of the disclosure.

FIG. 5 is a circuit diagram for four image sensor pixels with a shared floating diffusion, in accordance with an embodiment of the disclosure.

### DETAILED DESCRIPTION

Embodiments of an image sensor pixel and method for forming an image sensor pixel are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” or “in one example” means that a particular feature, structure, or characteristic described in connection with the embodiment is included in at least one embodiment of the present invention. Thus, the appearances of the phrases “in one embodiment” or “in an embodiment” or “in one example” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise.

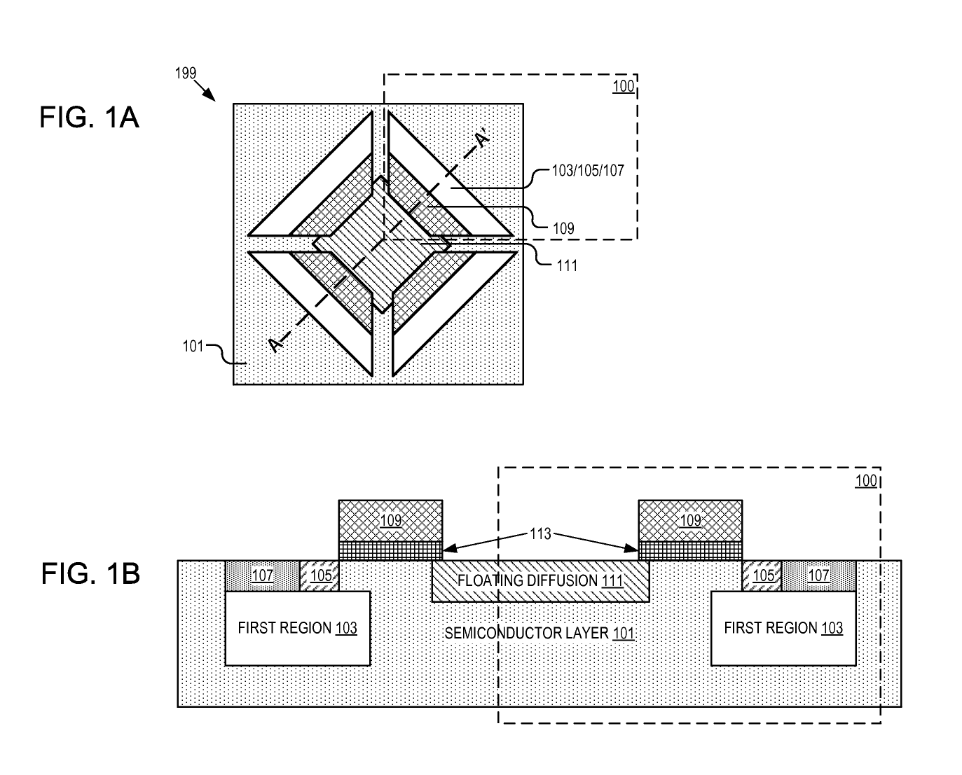

FIG. 1A is a top-down view of a shared pixel 199 that includes four image sensor pixels, in accordance with an embodiment of the disclosure. In the embodiment shown, shared pixel 199 includes image sensor pixel 100, which is one of the four image sensor pixels. The four image sensor pixels share the same floating diffusion 111. However, in a different embodiment any number of image sensor pixels can share the same floating diffusion 111 including configurations with two, six, and eight image sensor pixels sharing one floating diffusion 111. Individual image sensor pixels, including image sensor pixel 100, have individual transfer gates 109. In one embodiment, shared pixel 199 may include red, green, and blue image sensor pixels. In another or the same embodiment, shared pixel 199 may be arranged into a Bayer Pattern, X-Trans Pattern, EXR Pattern, or the like. However, shared pixel 199 should not just be limited to the capture of visible light, shared pixel 199 may also capture infrared or ultraviolet light depending on the doping schemes of the photodiodes and the presence of other pieces of device architecture not depicted.

FIG. 1B is a cross sectional view of the shared pixel 199 in FIG. 1A as cut along the line A-A′ illustrated in FIG. 1A, in accordance with an embodiment of the disclosure. Image sensor pixel 100 comprises a photodiode including a first dopant region 103, which is disposed within a semiconductor layer 101. In one embodiment, first dopant region 103 is n-type, and may be doped with Arsenic, Antimony, Phosphorus, or the like. Second dopant region 105 is disposed above first dopant region 103 within the semiconductor layer 101. Second dopant region 105 contacts first dopant region 103, and second dopant region 105 is of an opposite majority charge carrier type as first dopant region 103. A third dopant region 107 is also disposed above first dopant region 103 and within the semiconductor layer 101. Third dopant region 107 contacts first dopant region 103 and second dopant region 105, and third dopant region 107 is of a same majority charge carrier type as second dopant region 105. When first dopant region 103 is n-type, both second dopant region 105 and third dopant region 107 are p-type so that they are of the opposite majority charge carrier type as first dopant region 103. However, third dopant region 107 has a greater concentration of free charge carriers than second dopant region 105. Therefore, third dopant region 107 may have a higher concentration of p-type dopant than second dopant region 105.

As previously stated, in one embodiment, first dopant region 103 may contain an n-type dopant, second dopant region 105 may contain a p-type dopant, and third dopant region 107 may contain a p-type dopant with a higher concentration of dopant than second dopant region 105. In one embodiment, semiconductor layer 101 is doped and is of a same majority charge carrier type as second dopant region 105 and third dopant region 107. N-type dopant may include phosphorus or other electron rich elements. P-type dopant may include boron or other electron deficient elements.

Image sensor pixel 100 also includes a transfer gate 109 positioned to transfer photogenerated charge from the photodiode that includes first dopant region 103. Transfer gate 109 is disposed over a gate dielectric 113 for insulation. Additionally, in image sensor pixel 100 shown in FIG. 1B, lateral bounds (the left edge) of second dopant region 105, extend closer to an edge (the right edge) of transfer gate 109 than lateral bounds (the left edge) of third dopant region 107. In one embodiment, the lateral bounds of first dopant region 103 extend under transfer gate 109. In another or the same embodiment, the lateral bounds of second dopant region 105 extend under transfer gate 109. In another or the same embodiment, second dopant region 105 is disposed at a same depth in semiconductor layer 101 as third dopant region 107 (as illustrated).

Shared pixel 199 includes a shared floating diffusion 111 in the semiconductor layer 101. Shared floating diffusion 111 may be disposed on an opposite side of transfer gate 109 from first dopant region 103, second dopant region 105, and third dopant region 107. In embodiments where first dopant region 103 is n-doped, the floating diffusion 111 will also be n-doped.

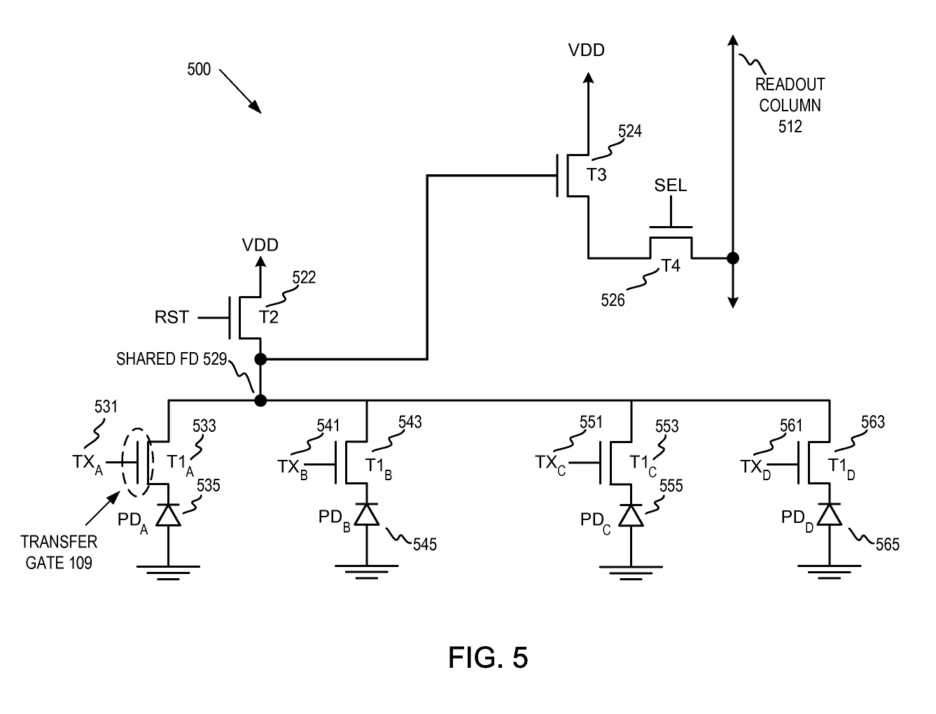

During operation, light enters the photodiode that includes first dopant region 103 and is converted into image charge. Voltage (that is greater than a threshold voltage) may be applied to each transfer gate 109 to read out the image charge from the image sensor pixels one at a time. However, image charge may be read out from multiple pixels at the same time by applying a voltage (that is greater than a threshold voltage) to multiple transfer gates 109 at the same time. Image charge is received by the floating diffusion 111 and may be read out by other pieces of the architecture (illustrated in FIG. 5).

It has been observed experimentally that forming a lightly doped second dopant region 105 in addition to forming a more heavily doped third dopant region 107 (as disclosed) results in an increased full well capacity and less total noise. The location of the different dopant regions relative to the transfer gate 109 may impact charge transfer from first dopant region 103 to floating diffusion 111. The disclosed configurations of dopant regions 103, 105, and 107 has also been observed to improve device performance by decreasing both dark current and the number of white pixels in image sensor pixels.

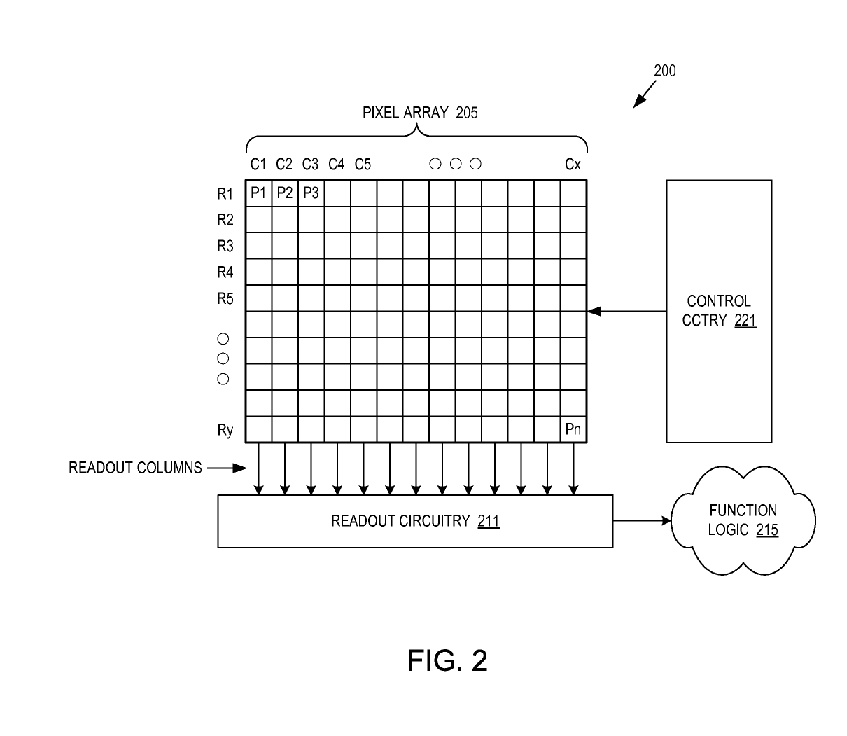

FIG. 2 is a block diagram illustrating one example of an image sensor 200, in accordance with an embodiment of the disclosure. In one example, pixel array 205 is a two-dimensional (2D) array of shared pixels 199, or image sensor pixels 100 (e.g., pixels P1, P2 . . . , Pn). As illustrated, shared pixels 199 are arranged into rows (e.g., rows R1 to Ry) and columns (e.g., column C1 to Cx) to acquire image data of a person, place, object, etc., which can then be used to render a 2D image of the person, place, object, etc.

In one example, after each image sensor pixel (including image sensor pixel 100) in pixel array 205 has acquired its image data or image charge, the image data is readout by readout circuitry 211 and then transferred to function logic 215. Readout circuitry 211 may be coupled to receive image data from the pixel array 205. In various examples, readout circuitry 211 may include amplification circuitry, analog-to-digital (ADC) conversion circuitry, or otherwise. Function logic 215 may simply store the image data or even manipulate the image data by applying post image effects (e.g., crop, rotate, remove red eye, adjust brightness, adjust contrast, or otherwise). In one example, readout circuitry 211 may readout a row of image data at a time along readout column lines (illustrated) or may readout the image data using a variety of other techniques (not illustrated), such as a serial readout or a full parallel readout of all pixels simultaneously.

In one example, control circuitry 221 is coupled to pixel array 205 to control operational characteristics of pixel array 205. Control circuitry 221 may be configured to control operation of the pixel array 205. For example, control circuitry 221 may generate a shutter signal for controlling image acquisition. In one example, the shutter signal is a global shutter signal for simultaneously enabling all pixels within pixel array 205 to simultaneously capture their respective image data during a single acquisition window. In another example, the shutter signal is a rolling shutter signal such that each row, column, or group of pixels is sequentially enabled during consecutive acquisition windows. In another embodiment, image acquisition is synchronized with lighting effects such as a flash.

In one embodiment, image sensor 200 may be included in a digital camera, cell phone, laptop computer, or the like. Additionally, image sensor 200 may be coupled to other pieces of hardware such as a processor, memory elements, output (USB port, wireless transmitter, HDMI port, etc.), lighting/flash, electrical input (keyboard, touch display, track pad, mouse, microphone, etc.), and/or display. Other pieces of hardware may deliver instructions to image sensor 200, extract image data from image sensor 200, or manipulate image data supplied by image sensor 200.

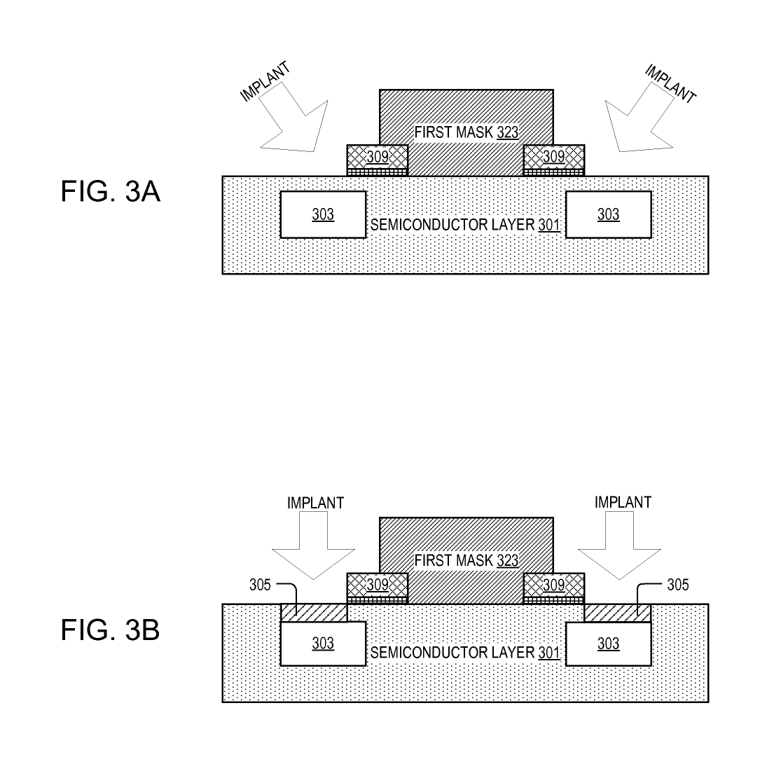

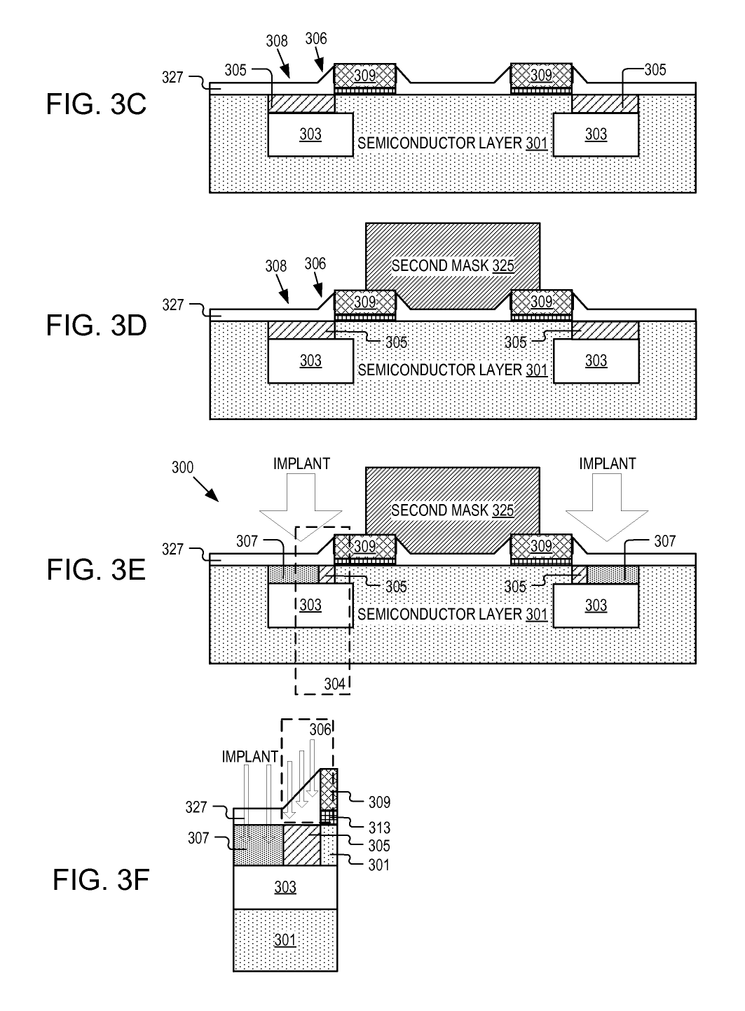

FIGS. 3A-3E, show a process for forming an image sensor pixel 300, in accordance with an embodiment of the disclosure. In one embodiment, image sensor pixel 300 may include semiconductor layer 301, first dopant region 303, second dopant region 305, third dopant region 307, transfer gate 309, and a floating diffusion (e.g. floating diffusion 111). The order in which some or all of the process occurs should not be deemed limiting. Rather, one of ordinary skill in the art having the benefit of the present disclosure will understand that some of the process may be executed in a variety of orders not illustrated, or even in parallel.

FIG. 3A shows the first dopant implantation. Prior to the first dopant implantation, transfer gates 309 are formed. During the first implantation, first dopant region 303 is formed in a semiconductor layer 301 using a first mask 323. First dopant region 303 extends into semiconductor layer 301 a first depth. Transfer gate 309 is positioned to transfer photogenerated charge from first dopant region 303 to a floating diffusion (e.g. floating diffusion 111). In one embodiment, first dopant region 303 is implanted using an angled implantation.

FIG. 3B shows the second dopant implantation. A second dopant region 305 is formed in the semiconductor layer 301 using first mask 323. Second dopant region 305 contacts first dopant region 303 and extends into semiconductor layer 301 a second depth which is less than the first depth (i.e. first dopant region 303 extends deeper into semiconductor layer 301 than second dopant region 305). In one embodiment, second dopant region 305 is p-doped and first dopant region 303 is n-doped (i.e. they are of the opposite majority charge carrier type). In one embodiment, the lateral bounds of second dopant region 305 extend under transfer gate 309. In another or the same embodiment, forming second dopant region 305 includes implanting second dopant at an angle normal to semiconductor layer 301.

FIG. 3C shows the formation of spacer layer 327 on semiconductor layer 301 prior to forming third dopant region 307. Shoulder regions 306 in spacer layer 327 are formed at edges of transfer gates 309, and shoulder regions 306 have a greater thickness than planar segments 308 of spacer layer 327.

FIG. 3D shows the placement of second mask 325. Second mask 325 is used in the third dopant implantation to form third dopant region 307. Second mask 325 may include photoresist.

FIG. 3E shows the third dopant implantation. A third dopant region 307 is formed in semiconductor layer 301 using second mask 325 and is implanted at an angle normal to the surface of semiconductor layer 301. Third dopant region 307 contacts second dopant region 305 and extends into semiconductor layer 301 a third depth which is less than the first depth (i.e. first dopant region 303 extends further into semiconductor layer 301 than third dopant region 307). Additionally, third dopant region 307 is of a same majority charge carrier type as second dopant region 305 and has a greater concentration of free charge carriers than second dopant region 305. For example, when second dopant region 305 and third dopant region 307 are p-type, third dopant region 307 has a higher p-type dopant concentration. Additionally, lateral bounds of second dopant region 305 extend closer to an edge of transfer gate 309 than lateral bounds of third dopant region 307.

In one embodiment, first dopant region 303 may contain an n-type dopant, second dopant region 305 may contain a p-type dopant, and third dopant region 307 may contain a p-type dopant with a higher concentration of dopant than second dopant region 305. In another or the same embodiment, multiple first, second, and third dopant regions 303, 305, 307 are formed to create multiple image sensor pixels. The multiple image sensor pixels may be arranged into a pixel array (e.g. pixel array 205) comprising rows and columns of image sensor pixels. Additionally, control circuitry and readout circuitry may be formed. In one example, control circuitry (e.g. control circuitry 221) is configured to control operation of the image sensor pixel 300 and readout circuitry (e.g. readout circuitry 211) is coupled to receive image data from image sensor pixel 300.

FIG. 3F is a magnified view of the structure within dashed line 304 of FIG. 3E, in accordance with an embodiment of the disclosure. It should be noted that a spacer layer 327 is disposed over semiconductor layer 301, and shoulder regions 306 in spacer layer 327 are disposed along at least one edge of transfer gate 309 (i.e. the edge nearest dopant region 303), and shoulder regions 306 have a greater thickness than planar segments 308 of spacer layer 327. Spacer layer 327 is formed on semiconductor layer 301 prior to forming third dopant region 307.

Although not pictured in FIGS. 3A-3F, in one embodiment, a shared floating diffusion is formed in semiconductor layer 301 (e.g. floating diffusion 111), and the shared floating diffusion is disposed on an opposite side of transfer gate 309 from first dopant region 303, second dopant region 305, and third dopant region 307. In one example, the shared floating diffusion is positioned to receive photogenerated charge from image sensor pixel 300 and at least one additional image sensor pixel.

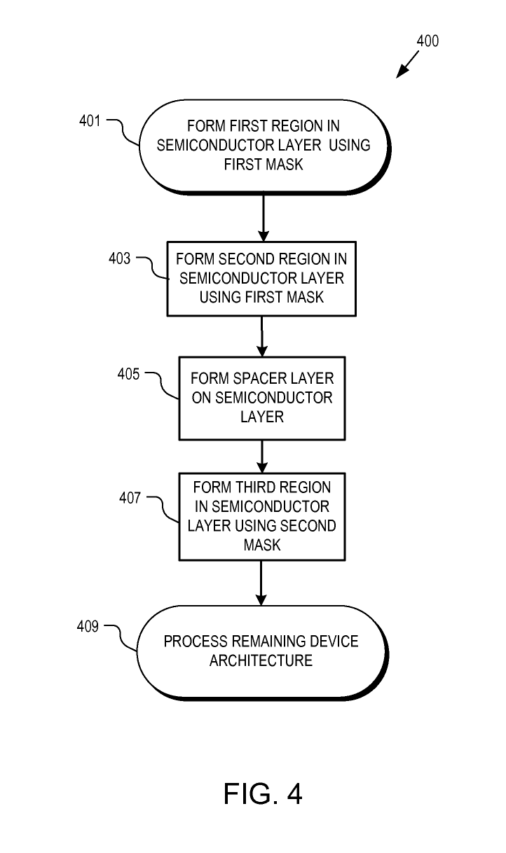

FIG. 4 is a flowchart of a process 400 for forming an image sensor pixel, in accordance with an embodiment of the disclosure. The order in which some or all of the process blocks appear in process 400 should not be deemed limiting. Rather, one of ordinary skill in the art having the benefit of the present disclosure will understand that some of the process blocks may be executed in a variety of orders not illustrated, or even in parallel.

Process block 401 illustrates forming a first region (e.g. first dopant region 303) in a semiconductor layer using a first mask. In one embodiment, the first region is an n-type region that extends under a transfer gate. In the same or a different embodiment, the dopant used to form the first region is phosphorus or other electron rich elements. The dopant may be implanted using ion implantation followed by subsequent annealing procedures.

In process block 403, a second region (e.g. second dopant region 305) is formed in the semiconductor layer using the first mask. In one embodiment the second region is a lightly doped p-type region and extends up to an edge of the transfer gate. The lightly doped p-type region may be formed using boron fluoride with an implantation energy of 14 KeV (resulting in an atomic concentration of 6×10¹²) atoms/cm³ in the semiconductor layer) or boron with an implantation energy of 4 KeV (resulting in an atomic concentration of 6×10¹²) atoms/cm³ in the semiconductor layer). However, it should be noted that a range of atomic concentrations and dopant materials may be used to achieve the same or a similar result. In the same or a different embodiment, the second region does not extend into the semiconductor layer as far as the first region.

Process block 405 illustrates forming a spacer layer (e.g. spacer layer 327) on the semiconductor layer. In one embodiment, the spacer layer is disposed over the semiconductor layer. Shoulder regions in the spacer layer are disposed along at least one edge of the transfer gate, and the shoulder regions have a greater thickness than planar segments of the spacer layer. In one embodiment, the spacer layer includes photoresist. In another embodiment, the spacer layer includes an oxide layer.

Process block 407 shows forming the third region (e.g. third dopant region 307) in the semiconductor layer using a second mask. The third region has a same majority charge carrier type as the second region but a higher dopant concentration. As previously stated, a spacer layer is formed on the semiconductor layer prior to forming the third dopant region.

The disclosed method of fabricating the image sensor pixels with the disclosed dopant region configuration may also be advantageous. First, process steps are saved by using mask 323 for the angled implant of dopant region 303 and then reusing first mask 323 for implanting dopant region 305. This reduces the masking steps required for fabrication. Second, the disclosed method can be executed using wafer-normal implants (i.e. non-angled implants) to form the pinning region (e.g. dopant regions 105 and 107) whereas two angled implants are typically required to form pinning regions above photodiodes in shared pixel configurations. Using wafer-normal implants reduces the implant steps required since multiple angled implants may be required to achieve symmetry of a shared pixel. Third, using second mask 325 in combination with spacer layer 327 defines dopant region 307 as dopant region 327 is self-aligned to be further from transfer gate 309 than dopant region 305. The self-alignment is a result of the already existing shoulder regions of spacer layer 327 having greater thickness than planar segments 308 of the spacer layer and the greater thickness prevents the third dopant implant from passing through the shoulder regions into semiconductor layer 301. Using the shoulder regions of spacer layer 327 to self-align dopant region 307 instead of a mask may save fabrication from an additional process step and/or a more accurate (and expensive) masking step to position region 307 slightly farther from transfer gate 309 than dopant region 305 is.

Remaining device architecture is processed in process block 409. In one embodiment, this includes processing conductive interconnects which attach to control and readout circuitry. In another or the same embodiment, a dielectric isolation layer is processed on top of the semiconductor layer. Additionally, an antireflection coating may be processed on top of the dielectric isolation layer such that the dielectric isolation layer is disposed between the semiconductor layer and the antireflection coating.

In another or the same embodiment, a light filter layer may be disposed on the side of the semiconductor layer that receives light and include individual light filters. The individual light filters may include red, green, and blue light filters. The light filters may be optically coupled to the image sensor pixels such that photons are transmitted from a light source through the light filters and into the image sensor pixels.

In one embodiment, pinning wells may be fabricated between image sensor pixels. The pinning wells may include a p-type or n-type doped region disposed in the semiconductor layer. The pinning wells may electrically isolate the image sensor pixels from one another to prevent crosstalk.

FIG. 5 is a circuit diagram 500 of a shared pixel (e.g. shared pixel 199) that includes four image sensor pixels with a shared floating diffusion, in accordance with an embodiment of the disclosure. The device represented by circuit diagram 500 utilizes a single shared floating diffusion 529 to receive charge from multiple photodiodes. Circuit diagram 500 includes four photodiodes PD_{A} 535, PD_{B} 545, PD_{C} 555, and PD_{D} 565; four transfer transistors T1_{A} 533, T1_{b} 543, T1_{c} 553, and T1_{d} 563; a reset transistor 522; source follower transistor 524; and row select transistor 526.

Each of first, second, third, and fourth transfer transistors 533, 543, 553 and 563 are coupled to first, second, third and fourth photodiodes PD_{A} 535, PD_{B} 545, PD_{C} 555, and PD_{D} 565, respectively and floating diffusion node 529, as seen in FIG. 5. A first, second, third and fourth transfer signal TX_{A} 531, TX_{B} 541, TX_{C} 551, and TX_{D} 561 are selectively applied to the gate terminals of first, second, third, and fourth transfer transistors 533, 543, 553, and 563. A reset transistor 522 is coupled between reset voltage source VDD and floating diffusion node 529. Source follower transistor 524 and row select transistor 526 are connected in series between power supply VDD and readout column 512.

In one embodiment, during one transfer period, one transfer signal is asserted (e.g. TX_{A} 531) to transfer charge from PD_{A} 535 to floating diffusion node 529 while TX_{B} 541, TX_{C} 551, and TX_{D} 561 are not asserted. In other embodiments, two or more transfer signals may be asserted to two or more transfer transistors to read out image charge of two or more photodiodes simultaneously.

In one embodiment, the transfer gate of transistor T1_{A} 533 corresponds to transfer gate 109 in FIG. 1A. Additionally, the shared pixel 199 of FIG. 1A may include the four photodiodes (PD_{A} 535, PD_{B} 545, PD_{C} 555, and PD_{D} 565), the four transistors (T1_{A} 533, T1_{b} 543, T1_{c} 553, and T1_{d} 563), and shared floating diffusion 529 of FIG. 5.

In one embodiment (not illustrated), reset transistor 522, source follower transistor 524, and row select transistor 526 are coupled to read out two shared pixels 199 having a total of eight photodiodes (each shared pixel has four photodiodes). In that embodiment, each shared pixel 199 has four photodiodes and a floating diffusion and the floating diffusions of the two shared pixels 199 are tied together and are coupled to reset transistor 522 and source follower 524 for readout onto readout column 512 when select transistor 526 is activated.

Embodiments of the present disclosure may be used for reading out an image sensor that includes other shared pixel architecture, such as eight-share or sixteen-share pixel units. For each of the transfer transistors in the shared pixel cells, one transfer signal is asserted, while the transfer voltage is applied to anywhere between one to all of the remaining non-transferring transfer transistors.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An image sensor pixel comprising:
a photodiode including a first dopant region disposed within a semiconductor layer;
a second dopant region disposed above the first dopant region and within the semiconductor layer, wherein the second dopant region contacts the first dopant region, and wherein the second dopant region is of an opposite majority charge carrier type as the first dopant region;
a third dopant region disposed above the first dopant region and within the semiconductor layer, wherein the third dopant region contacts the first dopant region and the second dopant region, and wherein the third dopant region is of a same majority charge carrier type as the second dopant region and has a greater concentration of free charge carriers than the second dopant region; and
a transfer gate positioned to transfer photogenerated charge from the photodiode, wherein the second dopant region extends closer to an edge of the transfer gate than the third dopant region.

2. The image sensor pixel of claim 1, wherein lateral bounds of the first dopant region extend under the transfer gate.

3. The image sensor pixel of claim 1, wherein the second dopant region extends under the transfer gate.

4. The image sensor pixel of claim 1, further comprising a spacer layer disposed over the semiconductor layer, wherein shoulder regions in the spacer layer are disposed along at least one edge of the transfer gate, and wherein the shoulder regions have a greater thickness than planar segments of the spacer layer.

5. The image sensor pixel of claim 1, wherein the first dopant region contains an n-type dopant, the second dopant region contains a p-type dopant, and the third dopant region contains a p-type dopant with a higher concentration of dopant than the second dopant region.

6. The image sensor pixel of claim 1, wherein the second dopant region is disposed at a same depth in the semiconductor layer as the third dopant region.

7. The image sensor pixel of claim 1, wherein the semiconductor layer is doped and is of a same majority charge carrier type as the second and third dopant regions.

8. The image sensor pixel of claim 1, further comprising a shared floating diffusion in the semiconductor layer, wherein the shared floating diffusion is disposed on an opposite side of the transfer gate from the first dopant region, the second dopant region, and the third dopant region.

9. The image sensor pixel of claim 1, wherein the second dopant region is disposed under a shoulder region of a spacer layer, and wherein the third dopant region is not disposed under the shoulder region, a lateral bounds of the third dopant region being aligned below an intersection of the shoulder region and a planar segment of the spacer layer.

10. A method of fabricating an image sensor pixel, the method comprising:
forming a transfer gate;
forming a first dopant region in a semiconductor layer using a first mask, wherein the first dopant region extends into the semiconductor layer a first depth, and wherein the transfer gate is positioned to transfer photogenerated charge from the first dopant region;
forming a second dopant region in the semiconductor layer using the first mask, wherein the second dopant region contacts the first dopant region and extends into the semiconductor layer a second depth which is less than the first depth, and wherein the second dopant region is of an opposite majority charge carrier type as the first dopant region; and
forming a third dopant region in the semiconductor layer using a second mask, wherein the third dopant region contacts the second dopant region and extends into the semiconductor layer a third depth which is less than the first depth, and wherein the third dopant region is of a same majority charge carrier type as the second dopant region and has a greater concentration of free charge carriers than the second dopant region, and wherein the second dopant region extends closer to an edge of the transfer gate than the third dopant region.

11. The method of claim 10, further comprising forming a spacer layer on the semiconductor layer prior to forming the third dopant region, wherein shoulder regions in the spacer layer are formed at edges of transfer gates, and wherein the shoulder regions have a greater thickness than planar segments of the spacer layer.

12. The method of claim 11, wherein forming the third dopant region includes an implantation with an angle normal to the semiconductor layer, and wherein dopant from the implantation is not implanted in the semiconductor layer beneath the shoulder regions.

13. The method of claim 10, wherein the second dopant region extend under the transfer gate.

14. The method of claim 10, wherein forming the first dopant region includes an angled implantation.

15. The method of claim 10, wherein forming the second dopant region includes an implantation with an angle normal to the semiconductor layer.

16. The method of claim 10, wherein the first dopant region contains an n-type dopant, the second dopant region contains a p-type dopant, and the third dopant region contains a p-type dopant with a higher concentration of dopant than the second dopant region.

17. The method of claim 10, further comprising forming a shared floating diffusion in the semiconductor layer, wherein the shared floating diffusion is disposed on an opposite side of the transfer gate from the first dopant region, the second dopant region, and the third dopant region.

18. The method of claim 17, wherein the shared floating diffusion is positioned to receive photogenerated charge from the image sensor pixel and at least one additional image sensor pixel.

19. The method of claim 10, wherein multiple first, second, and third dopant regions are formed to create multiple image sensor pixels.

20. The method of claim 19, wherein the multiple image sensor pixels are arranged into a pixel array comprising rows and columns of image sensor pixels.

21. The method of claim 10, further comprising forming control circuitry and readout circuitry, wherein the control circuitry is configured to control operation of the image sensor pixel and the readout circuitry is coupled to receive image data from the image sensor pixel.
